(19) United States
(12) Patent Application Publication
(10) Pub. No.: US 2026/0031792 A1
(43) Pub. Date: Jan. 29, 2026

(54) MULTILAYER PIEZOELECTRIC SUBSTRATE RESONATOR REFLECTOR STOPBAND SETTING

(71) Applicant: SKYWORKS SOLUTIONS, INC., Irvine, CA (US)

(72) Inventors: Masafumi Iwaki, Osaka-Shi (JP); Yiliu Wang, Irvine, CA (US)

(21) Appl. No.: 19/240,306

(22) Filed: Jun. 17, 2025

Related U.S. Application Data
(60) Provisional application No. 63/662,686, filed on Jun. 21, 2024.

(51) Int. Cl. H03H 9/64; H03H 9/02; H03H 9/145; H03H 9/25

(52) U.S. Cl. CPC H03H 9/6409; H03H 9/02637; H03H 9/145; H03H 9/25; H03H 9/6433

(57) ABSTRACT

Aspects and embodiments disclosed herein include a radio frequency filter including a plurality of surface acoustic wave resonators. At least one of the plurality of surface acoustic wave resonators is a notch resonator electrically connected to others of the plurality of surface acoustic wave resonators in a shunt configuration and having a resonant frequency above an upper end of a passband of the filter to improve signal rejection at the upper end of the passband of the filter.

### CROSS-REFERENCE TO RELATED APPLICATIONS

This application claims priority under 35 U.S.C. § 119(e) to U.S. Provisional Patent Application Ser. No. 63/662,686, titled “MULTILAYER PIEZOELECTRIC SUBSTRATE RESONATOR REFLECTOR STOPBAND SETTING,” filed Jun. 21, 2024, the entire content of which is incorporated herein by reference for all purposes.

### BACKGROUND

### Technical Field

Embodiments of this disclosure relate to acoustic wave devices and filters including same.

### Description of Related Technology

Acoustic wave devices, for example, surface acoustic wave (SAW) devices may be utilized as components of filters in radio frequency electronic systems. For instance, filters in a radio frequency front-end of a mobile phone can include acoustic wave filters. Two acoustic wave filters can be arranged as a duplexer.

### SUMMARY

In accordance with one aspect, there is provided a radio frequency filter including a plurality of surface acoustic wave resonators, at least one of the plurality of surface acoustic wave resonators being a notch resonator electrically connected to others of the plurality of surface acoustic wave resonators in a shunt configuration and having a resonant frequency above an upper end of a passband of the filter to improve signal rejection at the upper end of the passband of the filter.

In some embodiments, the notch resonator includes an interdigital transducer (IDT) electrode including IDT electrode fingers having a first pitch and reflector electrodes on either side of the IDT electrode in a direction of propagation of a main acoustic wave generated in the notch resonator, the reflector electrodes including reflector electrode fingers having a second pitch that is greater than the first pitch.

In some embodiments, an aperture of the notch resonator at least partially overlaps an aperture of at least one other of the plurality of surface acoustic wave resonators.

In some embodiments, the reflector electrodes of the notch resonator have stopbands with lower sides below a lower side of the passband of the filter.

In some embodiments, the pitch of the reflector electrode fingers is constant throughout the reflector electrodes.

In some embodiments, a subset of the reflector electrode fingers have a third pitch that is greater than the first pitch and less than the second pitch.

In some embodiments, the subset of the reflector electrode fingers in each of the reflector electrodes is disposed on inner portions of each of the reflector electrodes.

In some embodiments, the plurality of surface acoustic wave resonators includes a plurality of shunt acoustic wave resonators.

In some embodiments, the plurality of shunt acoustic wave resonators, other than the notch resonator, have IDT electrode fingers and reflector electrode fingers with substantially a same pitch.

In some embodiments, the plurality of surface acoustic wave resonators includes a plurality of series acoustic wave resonators.

In some embodiments, IDT electrode fingers of the plurality of series surface acoustic wave resonators have pitches that are less than pitches of reflector electrode fingers of the plurality of series surface acoustic wave resonators.

In some embodiments, at least one of the plurality of series surface acoustic wave resonators is a dual mode surface acoustic wave resonator.

In some embodiments, the filter is configured as a ladder filter.

In some embodiments, the filter is configured as a lattice filter.

In some embodiments, the filter is configured as a hybrid ladder-lattice filter.

In some embodiments, the filter is included in an electronics module.

In some embodiments, the electronics module is included in an electronic device.

### BRIEF DESCRIPTION OF THE DRAWINGS

Embodiments of this disclosure will now be described, by way of non-limiting example, with reference to the accompanying drawings.

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2 is a cross-sectional view of a portion of an example of a surface acoustic wave resonator;

FIG. 3 is a schematic diagram of a radio frequency ladder filter;

FIG. 4 is a schematic diagram of a band pass radio frequency filter including a dual mode surface acoustic wave resonator;

FIG. 5 illustrates an example of the physical layout of resonators in a filter as illustrated in FIG. 4;

FIG. 6 illustrates electrode finger pitches in an example of a notch resonator that may be used in an example of a filter as disclosed herein;

FIG. 7 illustrates simulated and measured admittance curves of an example of the filter as illustrated in FIG. 3 and a notch resonator having the electrode finger pitch profile as illustrated in FIG. 6;

FIG. 8A illustrates an electrode finger pitch profile in another example of a notch resonator that may be used in an example of a filter as disclosed herein;

FIG. 8B illustrates an electrode finger pitch profile in another example of a notch resonator that may be used in an example of a filter as disclosed herein;

FIG. 8C illustrates an electrode finger pitch profile in another example of a resonator that may be used in an example of a filter as disclosed herein;

FIG. 9 illustrates a comparison between the admittance curves of a filter as illustrated in FIG. 3 when utilizing a notch resonator with an electrode finger pitch profile as illustrated in FIG. 6 vs. when utilizing a notch resonator with an electrode finger pitch profile as illustrated in FIG. 8A;

FIG. 10 illustrates a schematic of an example of a ladder filter;

FIG. 11 illustrates a schematic of an example of a lattice filter;

FIG. 12 illustrates a schematic of an example of a hybrid ladder-lattice filter;

FIG. 13 is a block diagram of one example of a filter module that can include one or more surface acoustic wave filters according to aspects of the present disclosure;

FIG. 14 is a block diagram of one example of a front-end module that can include one or more filter modules according to aspects of the present disclosure; and

FIG. 15 is a block diagram of one example of a wireless device including the front-end module of FIG. 14.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

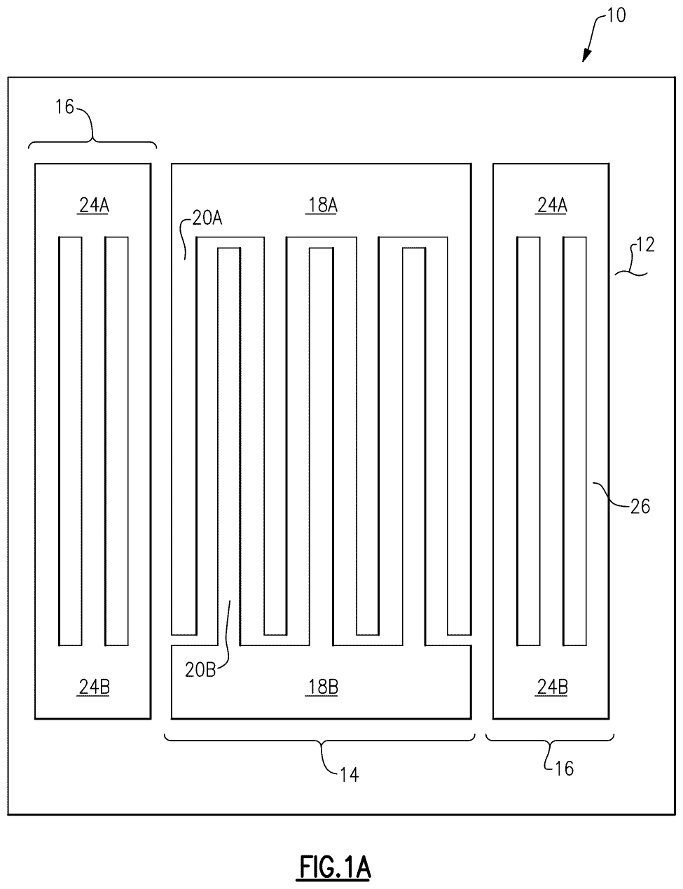

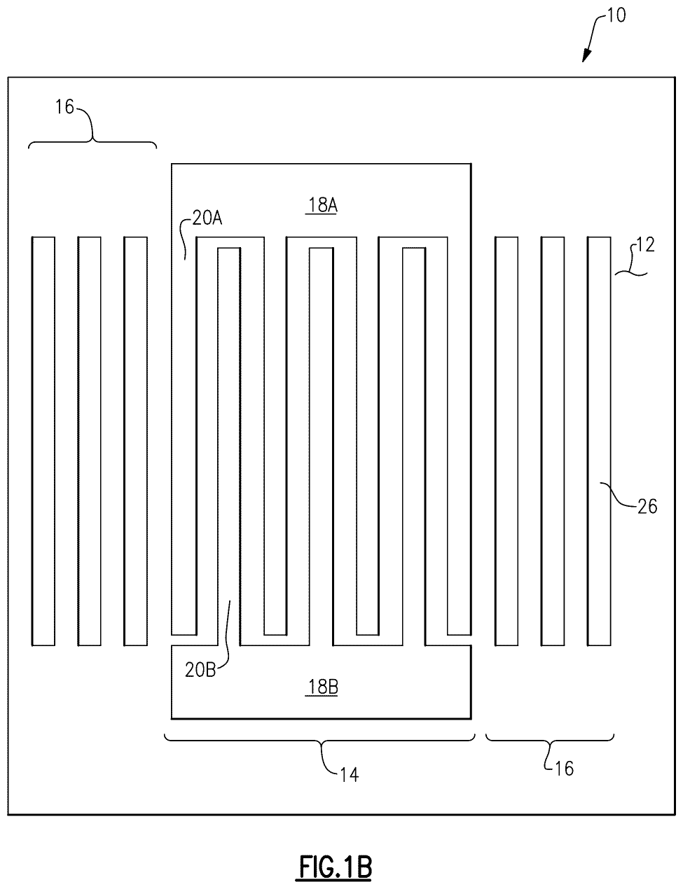

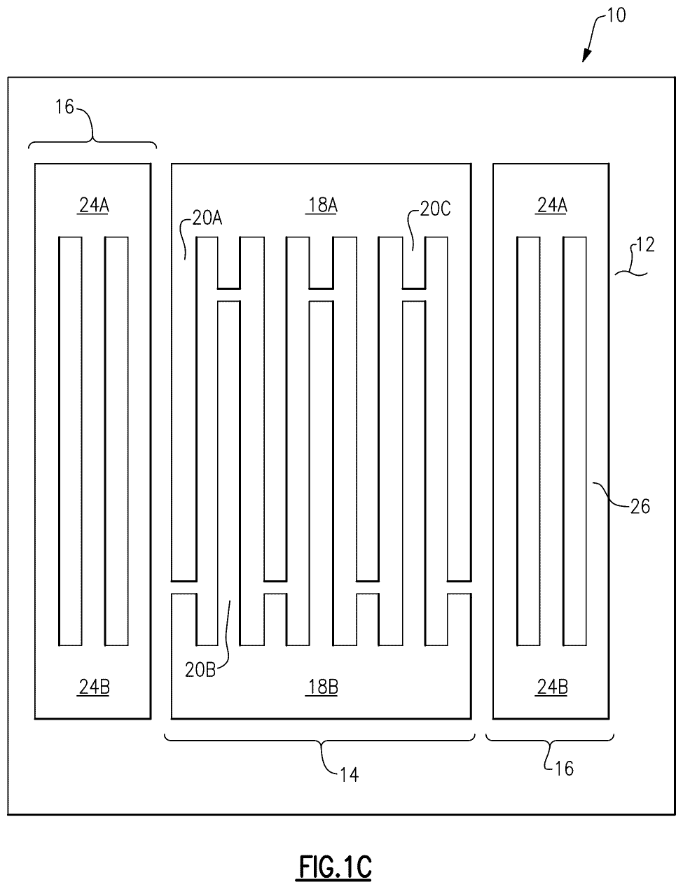

FIG. 1A is a plan view of a surface acoustic wave (SAW) resonator 10 such as might be used in a SAW filter, duplexer, balun, etc.

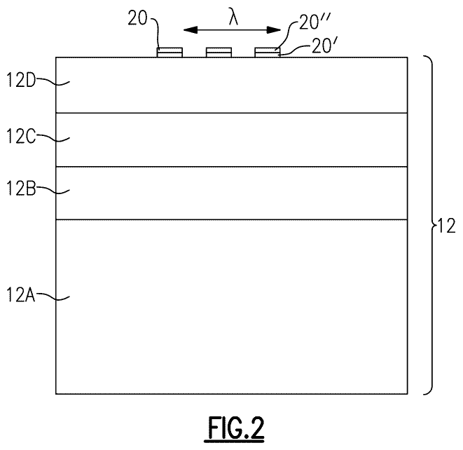

Acoustic wave resonator 10 is formed on a substrate 12 including a piezoelectric material layer, for example, a lithium tantalate (LiTaO₃) or lithium niobate (LiNbO₃) material layer. In some embodiments, as described with reference to FIG. 2 below, the substrate 12 may be a multilayer piezoelectric substrate (MPS). The acoustic wave resonator 10 includes an Interdigital Transducer (IDT) electrode 14 and reflector electrodes 16. In use, the IDT electrode 14 excites a main acoustic wave having a wavelength λ along a surface of the substrate 12. The reflector electrodes 16 sandwich the IDT electrode 14 and reflect the main acoustic wave back and forth through the IDT electrode 14. The main acoustic wave of the device travels perpendicular to the lengthwise direction of the electrode fingers of the IDT electrode.

The IDT electrode 14 include a first bus bar electrode 18A and a second bus bar electrode 18B facing the first bus bar electrode 18A. The IDT electrode 14 further includes first IDT electrode fingers 20A extending from the first bus bar electrode 18A toward the second bus bar electrode 18B, and second IDT electrode fingers 20B extending from the second bus bar electrode 18B toward the first bus bar electrode 18A.

The reflector electrodes 16 (also referred to as reflector gratings or simply reflectors) each include a first reflector bus bar electrode 24A and a second reflector bus bar electrode 24B and reflector electrode fingers 26 extending between and electrically coupling the first bus bar electrode 24A and the second bus bar electrode 24B.

In other embodiments disclosed herein, as illustrated in FIG. 1B, the reflector bus bar electrodes 24A, 24B may be omitted and the reflector electrode fingers 26 may be electrically unconnected. Further, as illustrated in FIG. 1C, acoustic wave resonators as disclosed herein may include dummy electrode fingers 20C that are aligned with respective IDT electrode fingers 20A, 20B. Each dummy electrode finger 20C extends from the opposite bus bar electrode 18A, 18B than the respective IDT electrode finger 20A, 20B with which it is aligned.

It should be appreciated that the acoustic wave resonators 10 illustrated in FIGS. 1A-1C, as well as the other circuit elements illustrated in other figures presented herein, are illustrated in a highly simplified form. The relative dimensions of the different features are not shown to scale. Further, typical acoustic wave resonators would commonly include a far greater number of IDT electrode fingers and reflector electrode fingers than illustrated. Typical acoustic wave resonators or filter elements may also include multiple IDT electrodes sandwiched between the reflector electrodes.

FIG. 2 illustrates a cross-section of the substrate 12 and electrodes 20 that may be utilized in surface acoustic wave devices, for example, as illustrated in any of FIGS. 1A-1C above. The electrodes 20 of FIG. 2 may be any of the IDT electrodes fingers 20A, 20B, the dummy electrodes 20C, or the reflector electrode fingers 26 of a surface acoustic wave device, for example, as illustrated in any of FIGS. 1A-1C above. The electrodes 20 will, however, be referred to herein as IDT electrodes 20. The IDT electrodes 20 may be multi-layer electrodes including a lower layer 20′ of a first metal and an upper layer 20″ of a second metal that is different from the first metal.

The substrate 12 is an MPS substrate including a support substrate 12A that may be formed of any of Si, quartz, sapphire, or any other suitable material to provide the substrate 12 with a desired amount of mechanical stability. A trap-rich layer 12B formed of, for example, polysilicon is disposed on top of the support substrate 12A and helps to reduce the generation of parasitic currents at the upper surface of the support substrate 12A. A layer 12C of a dielectric material, for example, a 600 nm thick layer of SiO₂ is disposed on the upper surface of the trap-rich layer 12B. Layer 12C may be referred to herein as a functional layer. A layer 12D of a piezoelectric material, for example, a 1,000 nm thick layer of lithium tantalate (LiTaO₃) or lithium niobate (LiNbO₃) is disposed on the upper surface of the layer 12C of dielectric material. The IDT electrodes 20 are disposed on the upper surface of the layer 12D of piezoelectric material. The piezoelectric material of layer 12D may exhibit a negative temperature coefficient of frequency. This may be compensated for by the positive temperature coefficient of frequency exhibited by the SiO₂ in the functional layer 12C.

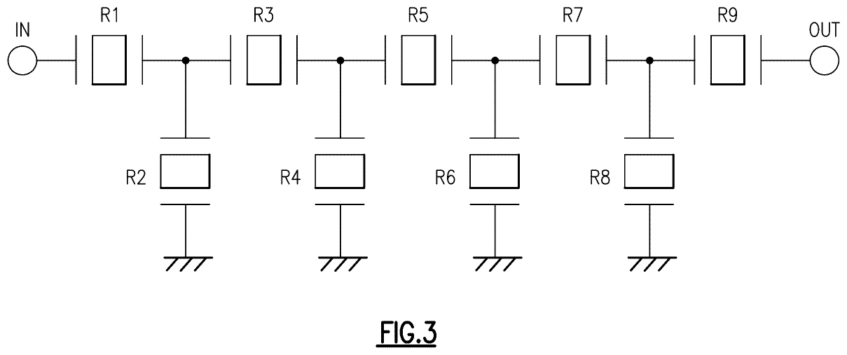

In some embodiments, multiple SAW resonators as disclosed herein may be combined into a filter, for example, an RF ladder filter as schematically illustrated in FIG. 3 and including a plurality of series resonators R1, R3, R5, R7, and R9, and a plurality of parallel or shunt resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

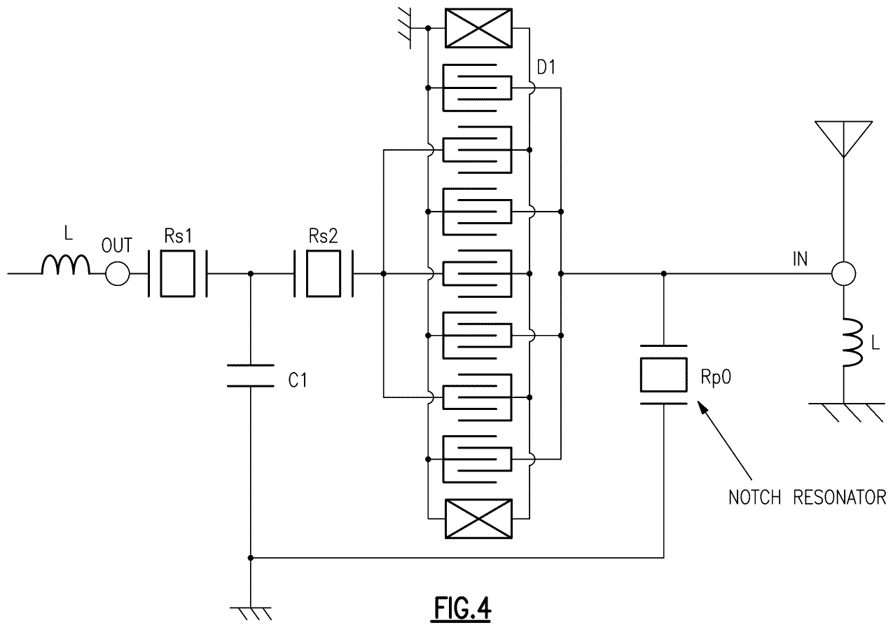

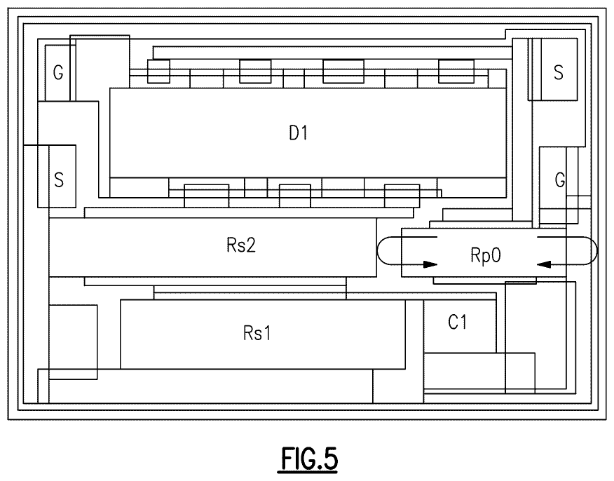

Another example of a SAW RF filter topology is illustrated in FIG. 4. The filter of FIG. 4 is configured as a receive filter with an antenna coupled to the input. The filter includes a dual mode SAW resonator D1, series resonators Rs1 and Rs2, a notch resonator Rp0 in a shunt configuration and a capacitor C1 and inductors L for impedance matching. An example of the physical layout of the resonators of the filter of FIG. 4 is shown in FIG. 5. As can be observed, the apertures of Rs2 and Rp0 partially overlap, which can cause signals generated in these two resonators to interfere with each other.

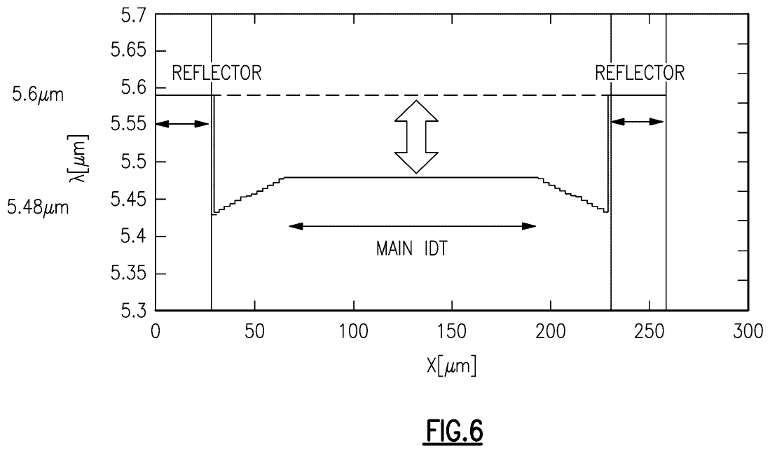

The notch resonator Rp0 is a high frequency shunt resonator with a resonant frequency fᵣ above the upper side of the filter passband and is used to improve filter passband high side rejection. The IDT and reflector electrode pitch profile for the notch resonator Rp0 may be set as illustrated in FIG. 6 to help suppress spurious signals generated in or leaking into the notch resonator. The IDT electrode finger pitch is constant across a center portion of the IDT electrode and decreases at outer sides of the IDT electrode. The reflector electrode finger pitch is set higher than the IDT electrode finger pitch. In the specific example shown in FIG. 6 the constant pitch portion of the IDT electrode has IDT electrode fingers with a pitch of about 5.48 μm while the reflector electrode finger pitch is set at about 5.6 μm. In this example, the reflector electrode finger pitch is 1.02 times (5.6/5.48=1.02) the constant region IDT electrode finger pitch. With these pitches the main acoustic wave generated by the constant pitch region of the IDT electrode has a frequency of about 665 MHz, while the reflectors electrodes have a reflectance at about 650.75 MHz and above, a difference of about 14 MHz. This can also be expressed as the reflector electrodes having a stopband with a lower side at about 650.75 MHZ.

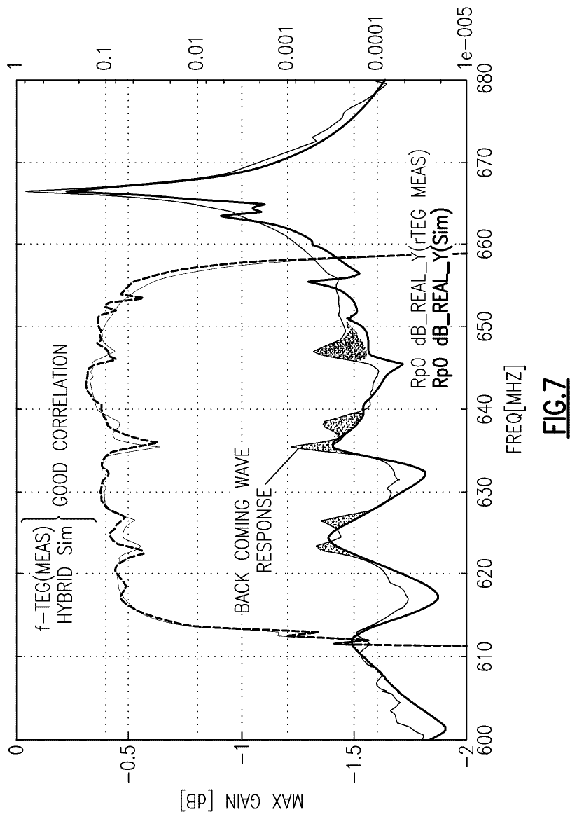

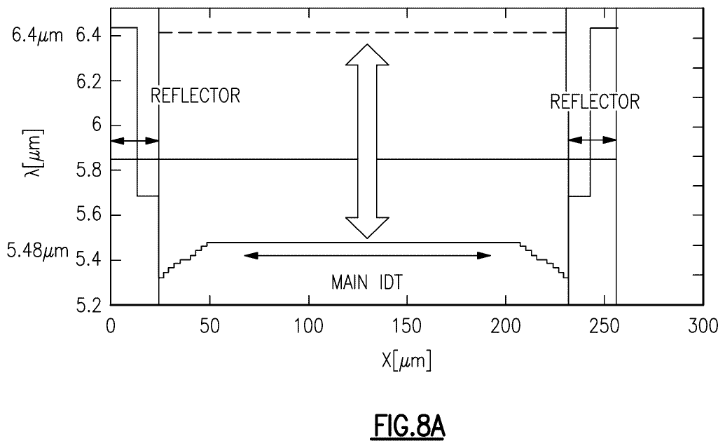

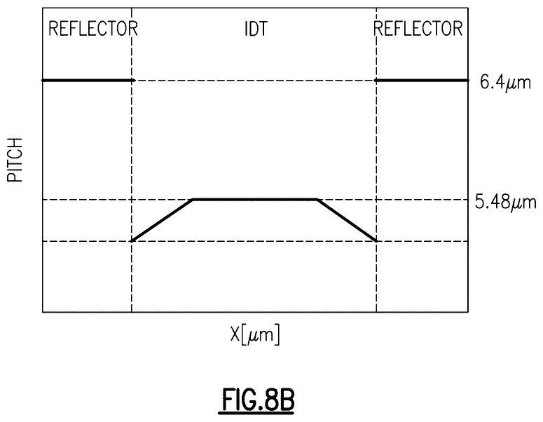

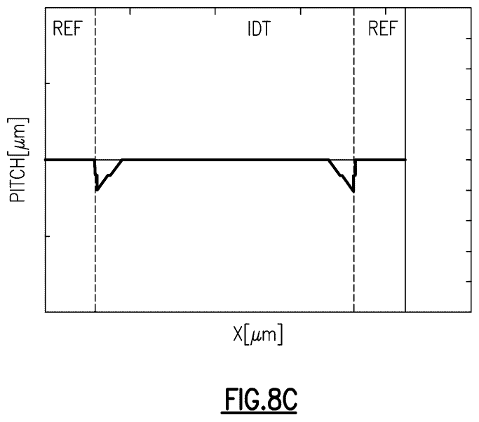

It has been observed that there may be some acoustic wave leakage through the reflector electrodes of the notch resonator into the IDT electrode of the notch resonator that leads to in-band filter performance degradation. This is believed to be due to the pitch of the reflector electrodes of the notch resonator being too low to sufficiently block signals from other resonators in the filter, for example, Rs2. FIG. 7 illustrates curves for both simulated and measured values of the admittance parameters of the notch resonator and of the filter as a whole when the filter is configured for use in the B71 frequency band. From FIG. 7 it can be seen that discontinuities in the notch resonator admittance, presumably due to leakage of acoustic waves into the notch resonator, correspond with admittance discontinuities in the passband of the filter. In FIG. 8 f-TEG represents data from the filter that can be probed after the front end process, while r-TEG represents data from a resonator that is probable after the front end process.

To help alleviate the problem with acoustic wave leakage into the notch resonator and the resultant discontinuities in the filter passband, the inventors have found that the pitch of the reflector electrode fingers of the notch resonator may be increased to a level at which the electrode fingers reflect signals with frequencies below the lower end of the filter passband and higher. In one example, illustrated in FIG. 8A, the maximum pitch of the reflector electrode fingers may be increased to about 6.4 μm, which will allow the reflector electrodes of the notch resonator to reflect signals with frequencies as low as about 569.4 MHZ, which is below the lower end of the passband of the filter and about 95.6 MHz below the frequency of the main acoustic wave generated by the constant pitch region of the IDT electrode. This can also be expressed as the reflector electrodes having a stopband with a lower side at about 569.4 MHz. In this example, the maximum reflector electrode finger pitch 1.17 times (6.4/5.48=1.17) the constant region IDT electrode finger pitch.

In some embodiments, the reflector electrode fingers may have pitches that increase in a stepwise manner with distance toward the outside of the reflector electrodes, as shown in FIG. 8A, while in other embodiments, the reflector electrode fingers may have constant pitches throughout as illustrated in FIG. 8B.

It is to be appreciated that the particular IDT electrode finger pitches and reflector electrode finger pitches described with reference to the examples above are particular to these examples. Other filters may include resonators with different IDT electrode finger pitches and reflector electrode finger pitches depending on factors such as the arrangement of resonators in the filters, the particular frequency bands at which the filters operate, the desired shape of their passband admittance curves, etc.

In a filter having the configuration shown in FIG. 4 with the notch resonator electrode finger pitch profile changed from that illustrated in FIG. 6 to that illustrated in FIG. 8A, the discontinuities in the admittance curve of the filter are significantly suppressed, as illustrated in the comparison of FIG. 9.

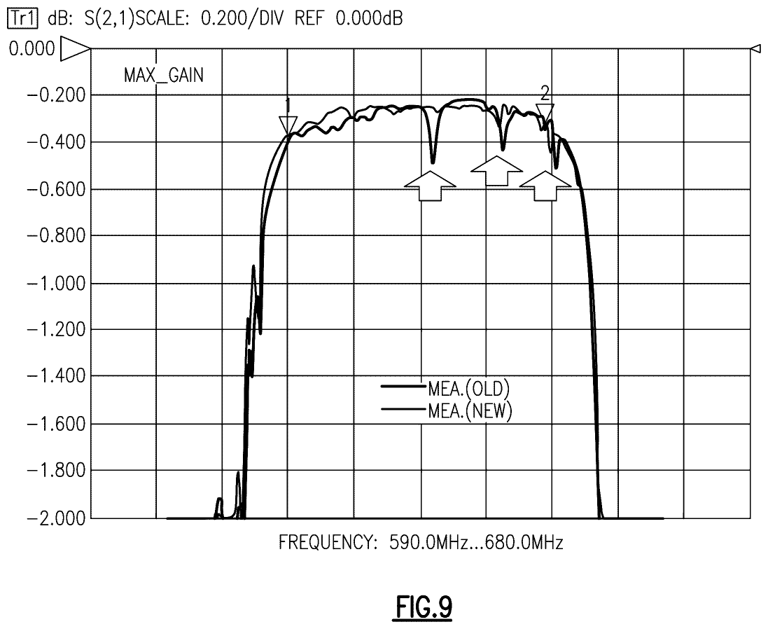

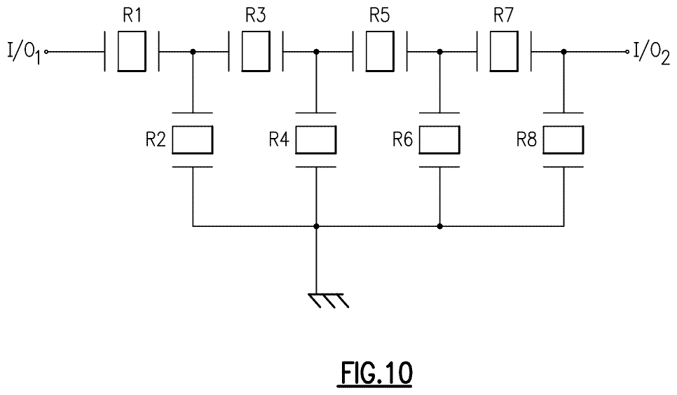

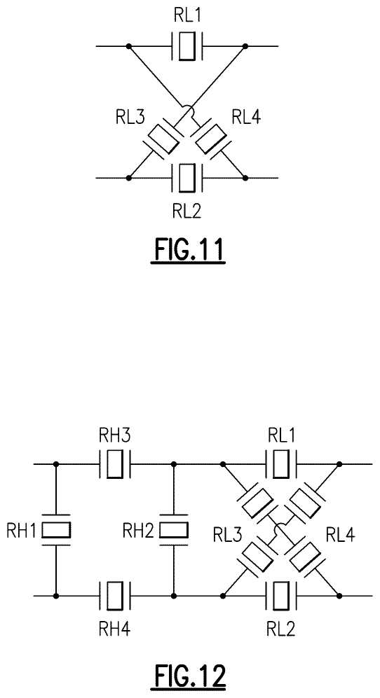

It is expected that similar improvements may be obtained in ladder filters, lattice filters, or hybrid ladder-lattice filters when a high frequency notch resonator is used to improve the rejection at the upper side of the filter passband and the reflector electrode fingers of the notch resonator have pitches set to cause the reflector stopband to have a side below the lower side of the filter passband. Examples of ladder filter, lattice filter, and hybrid ladder-lattice filter schematics are illustrated in FIGS. 10-12, respectively. Any of the shunt resonators in these examples may be the high frequency notch resonator.

In examples of these various filter types, series resonators may have electrode pitch profiles in which the reflector electrode finger pitches are greater than the IDT electrode finger pitches, for example, as illustrated in FIG. 6, 8A, or 8B, although it is to be understood that the particular electrode finger pitches may be different from those illustrated. Parallel or shunt resonators other than notch resonators as disclosed herein may have reflector electrode finger pitches that match, or at least substantially match the pitch of the IDT electrode fingers in the constant pitch region, for example, as illustrated in FIG. 8C.

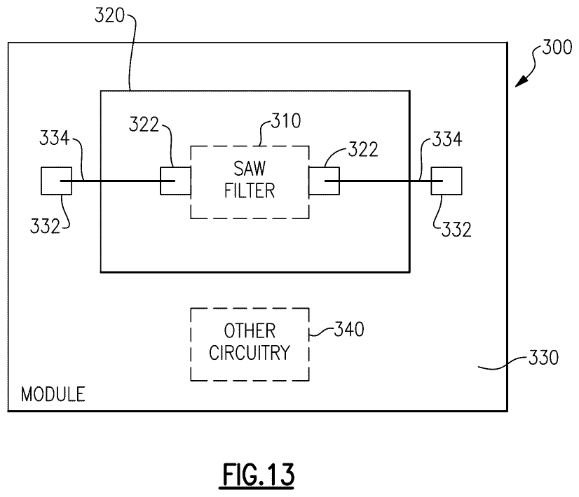

Examples of acoustic wave filters as disclosed herein can be implemented in a variety of packaged modules. Some example packaged modules will now be discussed in which any suitable principles and advantages of examples of the acoustic wave filters discussed herein can be implemented. FIGS. 13, 14, and 15 are schematic block diagrams of illustrative packaged modules and devices according to certain embodiments.

FIG. 13 is a block diagram illustrating one example of a module 300 including a SAW filter 310. The SAW filter 310 may be configured as an example of the acoustic wave filters discussed herein. The SAW filter 310 may be implemented on one or more die(s) 320 including one or more connection pads 322. For example, the SAW filter 310 may include a connection pad 322 that corresponds to an input contact for the SAW filter and another connection pad 322 that corresponds to an output contact for the SAW filter. The packaged module 300 includes a packaging substrate 330 that is configured to receive a plurality of components, including the die 320. A plurality of connection pads 332 can be disposed on the packaging substrate 330, and the various connection pads 322 of the SAW filter die 320 can be connected to the connection pads 332 on the packaging substrate 330 via electrical connectors 334, which can be solder bumps or wirebonds, for example, to allow for passing of various signals to and from the SAW filter 310. The module 300 may optionally further include other circuitry die 340, for example, one or more additional filter(s), amplifiers, pre-filters, modulators, demodulators, down converters, and the like, as would be known to one of skill in the art of semiconductor fabrication in view of the disclosure herein. In some embodiments, the module 300 can also include one or more packaging structures to, for example, provide protection and facilitate easier handling of the module 300. Such a packaging structure can include an overmold formed over the packaging substrate 330 and dimensioned to substantially encapsulate the various circuits and components thereon.

Various examples and embodiments of the SAW filter 310 can be used in a wide variety of electronic devices. For example, the SAW filter 310 can be used in an antenna duplexer, which itself can be incorporated into a variety of electronic devices, such as RF front-end modules and communication devices.

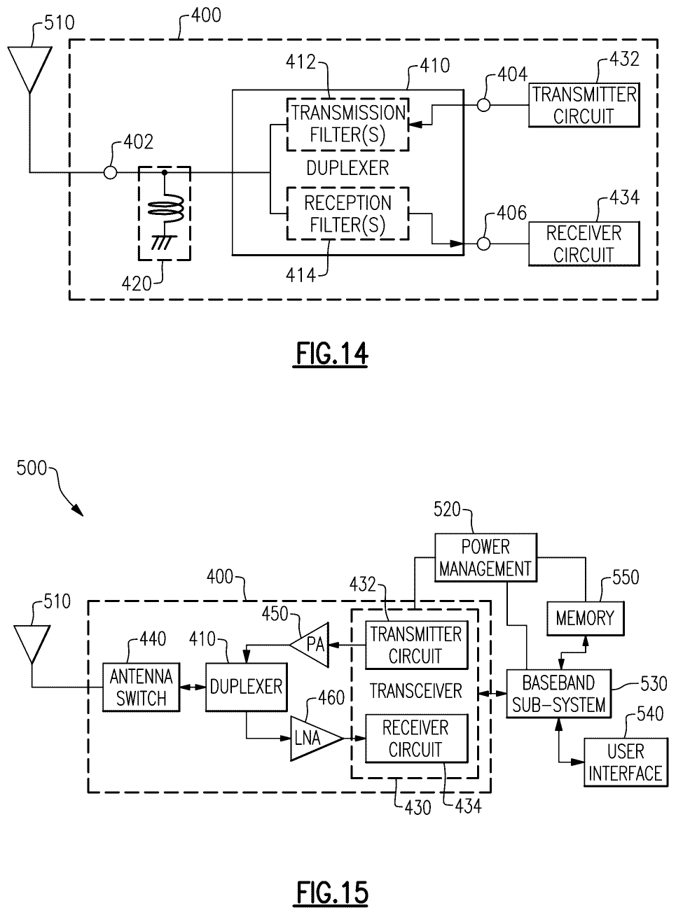

Referring to FIG. 14, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the SAW filter 310 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 14, however in other embodiments these components may be integrated into a common transceiver circuit or module. As will be appreciated by those skilled in the art, the front-end module 400 may include other components that are not illustrated in FIG. 14 including, but not limited to, switches, electromagnetic couplers, amplifiers, processors, and the like.

FIG. 15 is a block diagram of one example of a wireless device 500 including the antenna duplexer 410 shown in FIG. 14. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 14. The front-end module 400 includes the duplexer 410, as discussed above. In the example shown in FIG. 15 the front-end module 400 further includes an antenna switch 440, which can be configured to switch between different frequency bands or modes, such as transmit and receive modes, for example. In the example illustrated in FIG. 15, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 14.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 15, the front-end module 400 may further include a low noise amplifier module 460, which amplifies received signals from the antenna 510 and provides the amplified signals to the receiver circuit 434 of the transceiver 430.

The wireless device 500 of FIG. 15 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHZ.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A radio frequency filter including a plurality of surface acoustic wave resonators, at least one of the plurality of surface acoustic wave resonators being a notch resonator electrically connected to others of the plurality of surface acoustic wave resonators in a shunt configuration and having a resonant frequency above an upper end of a passband of the filter to improve signal rejection at the upper end of the passband of the filter.

2. The filter of claim 1 wherein the notch resonator includes an interdigital transducer (IDT) electrode including IDT electrode fingers having a first pitch and reflector electrodes on either side of the IDT electrode in a direction of propagation of a main acoustic wave generated in the notch resonator, the reflector electrodes including reflector electrode fingers having a second pitch that is greater than the first pitch.

3. The filter of claim 2 wherein an aperture of the notch resonator at least partially overlaps an aperture of at least one other of the plurality of surface acoustic wave resonators.

4. The filter of claim 2 wherein the reflector electrodes of the notch resonator have stopbands with lower sides below a lower side of the passband of the filter.

5. The filter of claim 2 wherein the pitch of the reflector electrode fingers is constant throughout the reflector electrodes.

6. The filter of claim 2 wherein a subset of the reflector electrode fingers have a third pitch that is greater than the first pitch and less than the second pitch.

7. The filter of claim 6 wherein the subset of the reflector electrode fingers in each of the reflector electrodes is disposed on inner portions of each of the reflector electrodes.

8. The filter of claim 1 wherein the plurality of surface acoustic wave resonators includes a plurality of shunt acoustic wave resonators.

9. The filter of claim 8 wherein the plurality of shunt acoustic wave resonators, other than the notch resonator, have IDT electrode fingers and reflector electrode fingers with substantially a same pitch.

10. The filter of claim 8 wherein the plurality of surface acoustic wave resonators includes a plurality of series acoustic wave resonators.

11. The filter of claim 10 wherein IDT electrode fingers of the plurality of series surface acoustic wave resonators have pitches that are less than pitches of reflector electrode fingers of the plurality of series surface acoustic wave resonators.

12. The filter of claim 10 wherein at least one of the plurality of series surface acoustic wave resonators is a dual mode surface acoustic wave resonator.

13. The filter of claim 1 configured as a ladder filter.

14. The filter of claim 1 configured as a lattice filter.

15. The filter of claim 1 configured as a hybrid ladder-lattice filter.

16. An electronics module comprising the filter of claim 1.

17. An electronic device including the electronics module of claim 16.
